(19) United States
(12) Patent Application Publication
(10) Pub. No.: US 2010/0091597 A1
(43) Pub. Date: Apr. 15, 2010

(54) SEMICONDUCTOR DEVICE

(75) Inventor: Tatsuya Matano, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc, Tokyo (JP)

(21) Appl. No.: 12/578,974

(22) Filed: Oct. 14, 2009

(30) Foreign Application Priority Data
Oct. 15, 2008 (JP) 2008-266589

(51) Int. Cl. G11C 5/14; H02J 1/00

(52) U.S. Cl. 365/226; 307/80

(57) ABSTRACT

A semiconductor device includes an internal voltage generating circuit which includes a first voltage generating circuit, a second voltage generating circuit having a higher current supply capability than the first voltage generating circuit, and a control circuit that controls switching between activation and inactivation of the second voltage generating circuit, using a first internal signal of the first voltage generating circuit.

### BACKGROUND OF THE INVENTION

1. Field of the Invention

This invention relates to a semiconductor device, and more particularly, to a semiconductor device including an internal voltage generating circuit, which generates and supplies an operation voltage for an internal circuit such as a memory circuit. Further particularly, this invention relates to a semiconductor device that supplies a driving voltage for the internal circuit as a load circuit.

Priority is claimed on Japanese Patent Application No. 2008-266589, filed Oct. 15, 2008, the content of which is incorporated herein by reference.

2. Description of the Related Art

To follow any required load variation, an internal voltage generating circuit requires an output circuit which is capable of coping with a maximum load current. In the internal voltage generating circuit which is capable of coping with the maximum load current, power consumption used by the internal voltage generating circuit is increased. Accordingly, even when a load current is small or even in the case of a standby mode used to activate the internal voltage generating circuit, significant power required for the internal voltage generating circuit with a large load current is consumed as long as the internal voltage generating circuit is activated. There has been proposed a technique for determining whether or not the output of such an internal voltage generating circuit is required, and if it is not required, for making the internal voltage generating circuit inactive to reduce power consumption. These are disclosed in Japanese Laid-open Patent Publication No. 2001-117650.

### SUMMARY

In one embodiment, a semiconductor device including an internal voltage generating circuit which may include, but is not limited to, a first voltage generating circuit, a second voltage generating circuit having a higher current supply capability than the first voltage generating circuit, and a control circuit that controls switching between activation and inactivation of the second voltage generating circuit, using a first internal signal of the first voltage generating circuit.

In another embodiment, a semiconductor device including an internal voltage generating circuit which may include, but is not limited to, a first voltage generating circuit, a second voltage generating circuit having a higher current supply capability than the first voltage generating circuit, and a control circuit that controls switching between activation and inactivation of the second voltage generating circuit, using a first internal signal of the first voltage generating circuit. The internal voltage generating circuit is connected to a power of an output circuit. The output circuit varies current consumption when outputting a control signal that selects at least one memory elements in a plurality of memory elements. The internal voltage generating circuit supplies the output circuit with a supply current that corresponds to the current consumption.

In still another embodiment, a semiconductor device may include, but is not limited to, a plurality of word lines, a plurality of bit lines, a plurality of memory cells being arranged at crossing points of the word lines and the bit lines, a plurality of word drivers that each drives the word line, and an internal voltage generating circuit that supplies an operation voltage to the word driver as a load circuit. The internal voltage generating circuit may include, but is not limited to, a first voltage generating circuit, a second voltage generating circuit having a higher current supply capability than the first voltage generating circuit, and a control circuit that controls switching between activation and inactivation of the second voltage generating circuit, using a first internal signal of the first voltage generating circuit.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing an internal voltage generating circuit according to a first embodiment of the present invention;

FIG. 2 is a block diagram showing a portion of a semiconductor device according to a second embodiment of the present invention; and

FIG. 3 is a waveform of word line drive signals and activation signals of the semiconductor device of FIG. 2.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

### First Embodiment

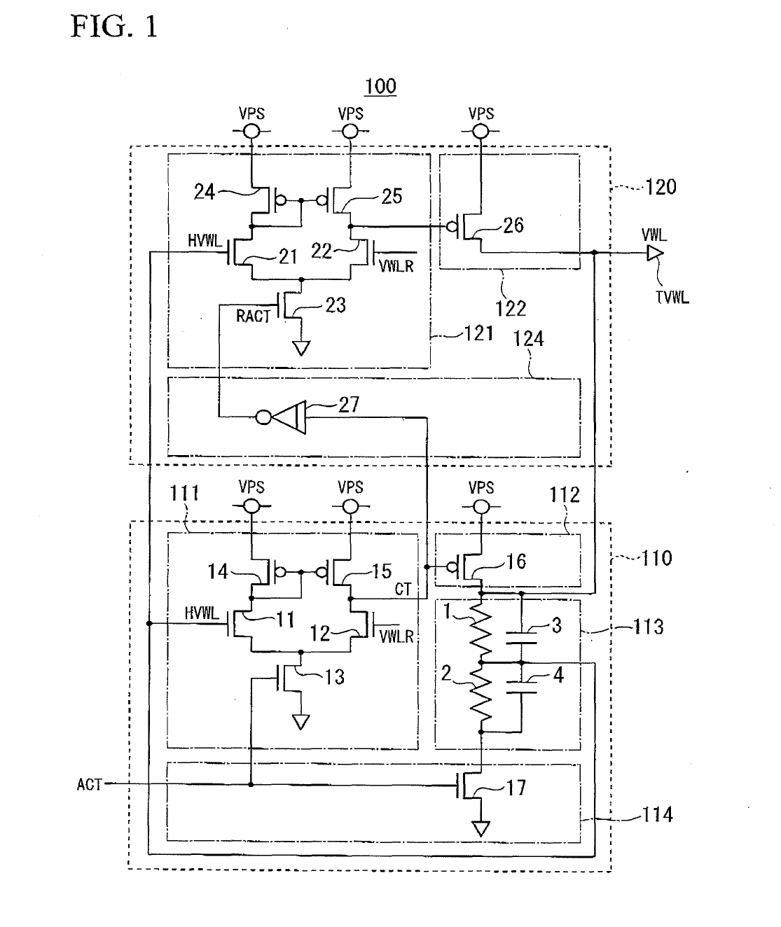

FIG. 1 is a block diagram showing an internal voltage generating circuit according to this embodiment. As shown in this figure, an internal voltage generating circuit 100 may include, but is not limited to, a voltage generating circuit 110 and a voltage generating circuit 120 with at least a higher current driving capability than that of the voltage generating circuit 110.

The voltage generating circuit 110 may include, but is not limited to, a differential amplifier circuit 111, an output circuit 112, a voltage divider circuit 113 and an activation control circuit 114.

The differential amplifier circuit 111 in the voltage generating circuit 110 may include, but is not limited to, an n-channel field effect transistor 11, hereinafter referred to as an “nMOSFET” 11), an nMOSFET 12, an nMOSFET 13, a p-channel field effect transistor 14 (hereinafter referred to as “pMOSFET” 14) and a pMOSFET 15.

The nMOSFET 11 in the differential amplifier circuit 111 has a gate connected to an output terminal of the voltage divider circuit 113. The nMOSFET 12 has a gate to which a reference voltage VWLR is input, and a source connected to a source of the nMOSFET 11. The nMOSFET 13 has a source connected to a ground potential, a drain connected to the source of the nMOSFET 11, and a gate connected to an input terminal to which an activation signal ACT is input. The pMOSFET 14 has a source connected to a power source VPS, a drain connected to a drain of the nMOSFET 11, and a gate connected to its own drain. The pMOSFET 15 has a source connected to the power source VPS, a drain connected to a drain of the nMOSFET 12, and a gate connected to the gate of the pMOSFET 14. An output terminal of the differential amplifier circuit 111 corresponds to the drain of the nMOSFET 12. More specifically, the differential amplifier circuit 111 is constituted by a differential input part including the nMOSFET 11 and the nMOSFET 12, a constant current circuit (nMOSFET 13) which is controlled by the input activation signal ACT and defines an operation current of the differential input part, and a current mirror part including the pMOSFET 14 and the pMOSFET 15, which serves as a load of the differential input part.

The output circuit 112 may include, but is not limited to, a pMOSFET 16. The pMOSFET 16 has a gate connected to the drain of the nMOSFET 12, a source connected to the power source VPS, and a drain connected to a resistor 1 of the voltage divider circuit and a power output terminal TVWL.

The voltage divider circuit 113 may include, but is not limited to, the resistor 1 and a resistor 2.

The voltage divider circuit 113 is connected to an output of the output circuit 112 and divides an output voltage of the output circuit 112, which is applied across the resistors 1 and 2 connected in series. The divided voltage is output from a junction point between the resistors 1 and 2. Capacitors 3 and 4 represent parasitic capacitance components due to stray capacitance or the like. In the voltage divider circuit 113, the capacitors 3 and 4 are respectively connected in parallel to the serial-connected resistors 1 and 2. That is, a feedback voltage based on the output voltage (load supply voltage) is obtained by the resistor voltage divider circuit. However, other configurations may be employed for the voltage divider circuit 113.

The activation control circuit 114 may include, but is not limited to, an nMOSFET 17. The nMOSFET 17 has a source connected to a reference potential, a drain connected to the resistor 2 of the voltage divider circuit 113, and a gate which is connected to an input terminal to which the activation signal ACT is input while branching the activation signal ACT to the differential amplifier circuit 111.

The voltage generating circuit 120 may include, but is not limited to, a differential amplifier circuit 121, an output circuit 122, and an activation control circuit 124.

The differential amplifier circuit 121 in the voltage generating circuit 120 may include, but is not limited to, the nMOSFET 21, the nMOSFET 22, the nMOSFET 23, the pMOSFET 24 and the pMOSFET 25. The differential amplifier circuit 121 is greater in amplification capability than the differential amplifier circuit 111.

The nMOSFET 21 in the differential amplifier circuit 121 has a gate connected to the output stage of the voltage divider circuit 113. The nMOSFET 22 has a gate to which the reference voltage VWLR is input, and a source connected to a source of the nMOSFET 21. The nMOSFET 23 has a source connected to the ground potential, a drain connected to the source of the nMOSFET 21, and a gate which is connected to an output terminal of the activation control circuit 124 and to which an activation signal RACT is input. The pMOSFET 24 has a source connected to the power source VPS, a drain connected to a drain of the nMOSFET 21, and a gate connected to its own drain. The pMOSFET 25 has a source connected to the power source VPS, a draM connected to a draM of the nMOSFET 22, and a gate connected to the gate of the pMOSFET 24. An output terminal of the differential amplifier circuit 121 corresponds to the drain of the nMOSFET 22. More specifically, the differential amplifier circuit 121 is constituted by a differential input part including the nMOSFET 21 and the nMOSFET 22, a constant current circuit (nMOSFET 23) which is controlled by an input control signal and defines an operation current of the differential input part, and a current mirror part including the pMOSFET 24 and the pMOSFET 25, which serves as a load of the differential input part.

The output circuit 122 may include, but is not limited to, a pMOSFET 26. The pMOSFET 26 has a gate connected to the drain of the nMOSFET 22, a source connected to the power source VPS, and a drain connected to the resistor 1 of the voltage divider circuit and the power output terminal TVWL.

The activation control circuit 124 (control circuit) may include, but is not limited to, a buffer 27. The buffer 27 receives the internal signal. The buffer 27 controls switching between activation and inactivation of the second voltage generating circuit 110. The buffer 27 has a threshold. The output from the buffer is inverted at the threshold. The threshold is set in relation to the voltage value of the internal signal at which a load current becomes exceeding a supply current. The load current is a current flowing through the load circuit that is connected commonly to outputs of the first and second voltage generating circuits 100 and 110. The supply current is a current supplied from the output circuit 122 of the first voltage generating circuit 110.

The buffer 27 has an input that is connected to an output terminal of the differential amplifier circuit 111 in the voltage generating circuit 110, that is, the drain of the nMOSFET 12. The buffer 27 has an output that is connected to an activation control input terminal of the differential amplifier circuit 121, that is, the gate of the nMOSFET 23. The activation control circuit 124 inputs the activation signal RACT to the differential amplifier circuit 121 according to a signal output by the differential amplifier circuit 111. The buffer 27 has an output circuit to output a signal indicating an activation state of the differential amplifier circuit 111 biased by a predetermined bias voltage. The buffer 27 outputs a “L (low)” level signal if the voltage of an input signal is lower than a threshold voltage, and outputs the bias voltage if the voltage of the input signal is larger than the threshold voltage. If the bias voltage is output, the differential amplifier circuit 111 is activated. Thus, a driving signal provided from the differential amplifier circuit 111 to the output circuit 112 in the voltage generating circuit 110 is supplied, as an internal signal CT of the voltage generating circuit 110, to the voltage generating circuit 120, and the same circuit 120 is controlled so as to be activated or inactivated by the internal signal CT. The activation control circuit 124 (control circuit) may be realized by the buffer 27 as shown in FIG. 1. It is possible to use another circuit configuration for the activation control circuit 124 (control circuit) instead of the buffer 27, provided that the internal signal CT is input into the activation control circuit 124 (control circuit), and the second voltage generating circuit 120 may assist the current supply capability of the first voltage generating circuit 110 under a predetermined condition or conditions. The predetermined condition or conditions may be decided based on a voltage level of the internal signal CT that controls the output circuit 112 of the first voltage generating circuit 110. There are a variety of circuit configurations available for the activation control circuit 124 (control circuit), provided that the available circuit has a threshold that is related to the voltage value of the internal signal CT to satisfy the predetermined condition or conditions.

A voltage VWL output from the internal power supply circuit 100 will be described. The voltage VWL is defined according to the following conditions.

In the voltage generating circuit 110, the differential amplifier circuit 111 compares a feedback signal HVWL, which is varied depending on an output voltage VWL, with a reference voltage VWLR, and detects the difference therebetween as an error signal. A signal, which is varied depending on the error signal and is used to control the voltage VWL output from the power supply circuit 110, functions as the internal signal CT of the power supply circuit 110.

The voltage generating circuit 110 may be realized by, but not limited to, a constant voltage circuit using a feedback amplifier circuit which controls the voltage VWL output according to the detected error signal.

A voltage obtained by dividing the voltage VWL output from the output circuit 112 by means of the voltage divider circuit 113 in the voltage generating circuit 110 is output as the feedback signal HVWL. The differential amplifier circuit 111 amplifies and outputs the power of the signal based on the error signal indicating the difference between a voltage of the feedback signal HVWL and the reference voltage VWLR (control-targeted voltage). A voltage power-amplified and output by the output circuit 112 based on the error signal corresponds to the voltage VWL. In this manner, the voltage VWL of the output signal is controlled such that a constant voltage is output by the feedback control circuit.

The voltage VWL of the signal output at this time can be expressed by the following Equation (1).

VWL=VWLR×(R1+R2)/R2 (1)

In Equation (1), R1 and R2 respectively represent values of the resistors 1 and 2, and VWLR represents a voltage value of the reference voltage VWLR. For the purpose of simplicity of description, it is assumed that there is no effect from the parasitic capacitance indicated by the capacitors 1 and 2.

Similarly, for the voltage generating circuit 120, since the differential amplifier circuit 121 in the same circuit 120 compares the feedback voltage and the reference voltage VWLR, the above Equation (1) is established.

With the above configuration, each of the voltage generating circuits 110 and 120 perform a feedback operation so that the feedback voltage (the voltage at the junction point between the resistors 1 and 2 of the voltage divider circuit 113) can be equal to the reference voltage VWLR in its activation state, and the output voltage VWL of the output terminal TVWL assumes a value of Equation (1) as the output voltage VWL is stabilized. More specifically, if the output voltage VWL is decreased due to an increase in current consumption in the load circuit connected to the output terminal TVWL, a diving signal to the output circuit 112 (122) and hence to the differential amplifier circuit 111 (121), that is, a gate voltage of the pMOSFET 16 (26), is lowered, its conductance accordingly increases (i.e., its conductive resistance is decreased), and, as a result, the output voltage VWL is controlled so as to be increased. On the other hand, if the output voltage VWL is increased due to reduction of the load connected to the output terminal TVWL, a driving signal to the output circuit 112 (122) and hence to the differential amplifier circuit 111 (121), that is, a gate voltage of the pMOSFET 16 (26), is raised, its conductance accordingly decreases (i.e., its conductive resistance increases), and, as a result, the output voltage VWL is controlled so as to be decreased. In this manner, the output voltage VWL is stabilized against load variations.

In this embodiment, current supply capability of the voltage generating circuit 110 is set to be relatively small (for example, a value smaller than the maximum consumption current of the load circuit), while current supply capability of the voltage generating circuit 120 is set to be relatively large (for example, a value larger than the maximum consumption current of the load circuit). The current supply capability is set depending on driving capability based on the size or the like of the pMOSFETs 16 and 26. In addition, the voltage generating circuit 120 is controlled so as to be activated or inactivated by the internal signal CT from the voltage generating circuit 110 with smaller current driving capability. Thus, if the output voltage VWL is lowered due to a significant increase in the load current (for example, a change from an idle current to a current exceeding the current supply capability of the voltage generating circuit 110), the voltage generating circuit 120 with larger current driving capability is activated, and, as a result, a load supply voltage is stabilized while power consumption is reduced.

In other words, the voltage generating circuit 110 is operated and activated by an active high level of the activation signal ACT, while being stabilized such that the output voltage VWL of the output terminal TVWL is the voltage expressed by the above Equation (1) in the normal state. The load current is varied depending on an operation state of the load circuit, however, if a variation of the load current falls within the range of driving capability of the voltage generating circuit 110, the output voltage VWL is still stabilized by the same circuit 110. In this state, since a threshold of the buffer 27 of the voltage generating circuit 120 is set to be smaller than a level of the internal signal CT of the voltage generating circuit 110 and accordingly the output of the buffer 27 is a “L (low)” level which is an inactive level, the nMOSFET 23 is turned off and the voltage generating circuit 120 does not operate. The threshold of the buffer 27 may be appropriately set from the viewpoint of intended circuit operation or power consumption.

If the load current is increased so as to exceed the driving capability of the voltage generating circuit 110, the stabilization control by the same circuit 110 cannot follow such an increase and thus the output voltage VWL is significantly lowered such that it cannot be stabilized. Accordingly, the output of the differential amplifier circuit 111 of the voltage generating circuit 110, that is, the level of the internal signal CT, is lowered until it becomes smaller than the threshold of the buffer 27.

As a result, the voltage generating circuit 120 is activated and its output circuit 122 is in an operation mode. Since the current driving capability of the voltage generating circuit 120 is set to be higher than the load current, it will be understood that the output voltage VWL can be rapidly stabilized.

Thus, the internal voltage generating circuit 100 of the present invention can realize the stabilization of the load supply voltage while power consumption is reduced.

In this manner, an internal voltage generating circuit (internal voltage generating circuit 100) according to this embodiment includes a first voltage generating circuit (voltage generating circuit 110) and a second voltage generating circuit (voltage generating circuit 120) with higher current supply capability than that of the first voltage generating circuit (voltage generating circuit 110) and has the function of controlling switching between activation and inactivation of the second voltage generating circuit (voltage generating circuit 120) using an internal signal of the first voltage generating circuit (voltage generating circuit 110).

With such configuration, the first voltage generating circuit decreases a voltage of an output signal if a current output from the first voltage generating circuit is greater than a predetermined current value (rated output current value). The first voltage generating circuit detects that the output current (supply current) exceeds the predetermined current value, and varies its internal signal. Depending on the state of the internal signal, the first voltage generating circuit activates the second voltage generating circuit and also outputs a current from the second voltage generating circuit. A current supplied to the load circuit connected to the first voltage generating circuit and second voltage generating circuit can be a large output current, which is an addition of the current output from the first voltage generating circuit and the current output from the second voltage generating circuit.

Accordingly, a value of a current output which changes in accordance with a variation of the load can be changed. That is, only the first voltage generating circuit with less power consumption is activated if the output current (supply current) is small, while the second voltage generating circuit with more power consumption but larger current supply capability is also activated if the output current (supply current) is large, thereby allowing switching between current supply outputs of the voltage generating circuits. In this manner, it is possible to switch between generations of power consumption of the voltage generating circuits depending on the current supply capability without providing a separate switch discriminating circuit, which results in circuit simplification.

In addition, in the internal voltage generating circuit (internal voltage generating circuit 100) of the semiconductor device according to this embodiment, the first voltage generating circuit (voltage generating circuit 110) includes an output circuit (output circuit 112) to control its output voltage and a driving signal to this output circuit (output circuit 112) is supplied, as an internal signal, to the second voltage generating circuit (voltage generating circuit 120).

With this configuration, the internal voltage generating circuit (internal voltage generating circuit 100) controls activation of the second voltage generating circuit (voltage generating circuit 120) using the internal signal output by the first voltage generating circuit (voltage generating circuit 110) and switches a current output of the second voltage generating circuit (voltage generating circuit 120). Such a switching allows addition and combination of output currents (supply currents) through control of the second voltage generating circuit (voltage generating circuit 120).

Accordingly, in switching between outputs of the voltage generating circuits, the internal voltage generating circuit (internal voltage generating circuit 100) can be configured without providing an additional switch discriminating circuit which may make the circuit complicated, thereby providing a semiconductor device with the internal voltage generating circuit (internal voltage generating circuit 100) which has simple configuration and reduced power consumption.

In addition, in the internal voltage generating circuit (internal voltage generating circuit 100) of the semiconductor device according to this embodiment, the first voltage generating circuit (voltage generating circuit 110) may further include a differential amplifier circuit (differential amplifier circuit 111) to generate a driving signal by comparing a feedback voltage, which is generated based on an output signal, with a reference voltage. The second voltage generating circuit (voltage generating circuit 120) may further include a differential amplifier circuit (differential amplifier circuit 121) to compare a feedback voltage and a reference voltage, with an output circuit (output circuit 122) which is driven by the differential amplifier circuit (differential amplifier circuit 121) and has an output connected in common to the output of the first voltage generating circuit (voltage generating circuit 110). An internal signal is supplied to the differential amplifier circuit (differential amplifier circuit 121) of the second voltage generating circuit (voltage generating circuit 120). The second voltage generating circuit (voltage generating circuit 120) switches between activation and inactivation states.

With this configuration, depending on a change in an output voltage, an internal signal is output based on a change in an error voltage detected in the first differential amplifier circuit (differential amplifier circuit 111). Using this internal signal, an output current (supply current) of the first output circuit (output circuit 112) is controlled while an output current (supply current) of the second output circuit (output circuit 122) is controlled. The output current that is output from the second output circuit (output circuit 122) controls activation of the second differential amplifier circuit (differential amplifier circuit 121) according to the internal signal output by the first voltage generating circuit (voltage generating circuit 110). The activated second differential amplifier circuit (differential amplifier circuit 121) allows a required current to be output from the second output circuit (output circuit 122) and stabilizes an output voltage.

In addition, with this configuration, using the internal voltage generating circuit (internal voltage generating circuit 100), it is possible to output a stable signal without being affected by load variation of the load circuit. The internal voltage generating circuit (internal voltage generating circuit 100) is configured in combination with the second voltage generating circuit (voltage generating circuit 120) which can detect the internal signal of the first voltage generating circuit (voltage generating circuit 110). In addition, this allows switching of current supply capability to follow the load variation of the load circuit connected to the internal voltage generating circuit (internal voltage generating circuit 100) without providing a separate switch discriminating circuit. With this configuration, it is possible to switch between generations of power consumption in the internal voltage generating circuit (internal voltage generating circuit 100), thereby providing an internal voltage generating circuit with simplified circuit configuration.

### Second Embodiment

A second embodiment of the present invention will be described, which shows a semiconductor device which supplies power to an output circuit with varying power consumption by outputting a control signal to select a particular memory element from a memory region including a plurality of memory elements using an internal voltage generating circuit which controls switching between activation and inactivation of a voltage generating circuit provided together using an internal signal of the voltage generating circuit.

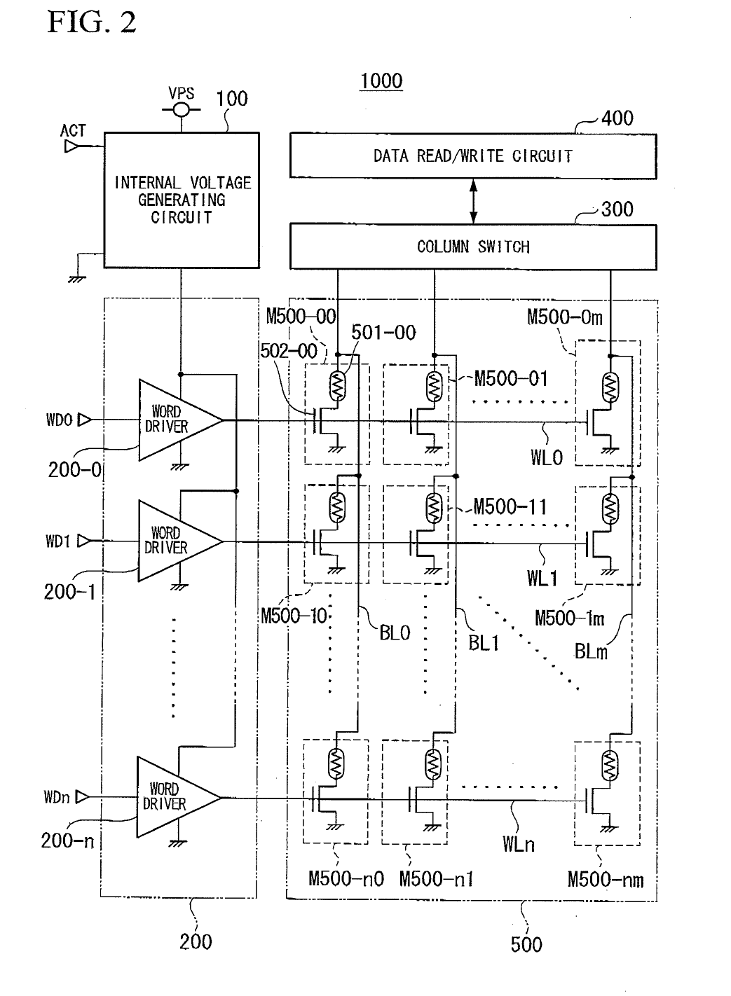

FIG. 2 is a block diagram showing a portion of a semiconductor device according to this embodiment.

As shown in the figure, a memory circuit (semiconductor device) 1000 employs variable-resistance memory elements as its memory elements (memory cells) and includes an internal voltage generating circuit 100, a word driver 200, a column switch 300, a data read/write circuit 400, a memory cell region 500, word lines WL0, WL1, . . . , WLn (hereinafter sometimes referred generally to as “word lines WL”), and bit lines BL0, BL1, . . . , BLm (hereinafter sometimes referred generally to as “bit lines BL”). In addition, although the memory circuit 1000 further includes various components such as a command processing system, an address processing system, a data input/output system and so on, it is to be understood that these components are omitted for the purpose of clarity of the figure. In addition, although the memory circuit 1000 is shown to be configured in the unit of semiconductor memory devices, it may be configured as a memory circuit in combination with a logic circuit, which is a so-called system LSI.

The internal voltage generating circuit 100 in the memory circuit 1000 has the same configuration as that shown in FIG. 1.

The memory cell region 500 in the memory circuit 1000 forms a memory cell array including a plurality of memory cells M500-00, . . . , M500-nm. The memory cells M500-00 to M500-nm may be generally referred to as “memory cell M500.” A memory cell M500-k1 is arranged at an intersection of a word line WLk and a bit line BL1 forming a matrix, and is selected by the connected word line WLk and bit line BL1. Each memory cell M500 is a memory element adopting a phase-change technique, which is constituted by a field effect transistor (FET) 502-00 and a phase-change element 501-00 using a phase-change film, as illustrated in the memory cell M500-00. The FET 502-00 has a gate connected to a word line WL0, a drain connected to a bit line BL0 via a phase-change element 502-00, and a source connected to a reference potential (ground). Hereinafter, field effect transistors included in each memory cell M500 are generally referred to as “FET 502.” The order of the phase-change memory element 501 and the FET 502 connected in series between the bit lines BL and the reference potential (ground) in each memory cell M500 may be reversed to the order shown in the figure.

A memory cell connected to the word lines WL connected to the word driver 200 is selected and the selected memory cell M500 is connected to the bit lines BL.

A gate of the FET 502 included in the memory cells M500-00, M500-01, . . . , M500-0n is connected to the word line WL0. A gate of the FET 502 included in the memory cells M500-10, M500-11, . . . , M500-1n is connected to the word line WL1. Similarly, a gate of the FET 502 included in the memory cells M500-m0, M500-m1, . . . , M500-mn is connected to the word lines WL. A drain of the FET 502 included in the memory cells M500-00, M500-10, . . . , M500-m0 is connected to the bit line BL0 via the phase-change element. A drain of the FET 502 included in the memory cells M500-01, M500-11, . . . , M500-m1 is connected to the bit line BL1 via the phase-change element. Similarly, a drain of the FET 502 included in the memory cells M500-0n, M500-1n, . . . , M500-mn is connected to the bit line BLm via the phase-change element. A source of the FET 502 included in each memory cell M500 is connected to the reference potential.

The word driver 200 outputs selection signals to each of the corresponding word lines WL according to signals WD0, WD1, . . . , WDn which select rows of the memory cell region 500, which are input from a word decoder (not shown). The word driver 200 includes word drivers 200-0, 200-1, . . . , 200-n (sometimes referred generally to as “word driver 200.” Each word driver 200 is connected to a corresponding word line WL and outputs a selection signal to the selected word lines WL.

The column switch 300 is interposed between the bit lines BL and the data read/write circuit 400 and connects one bit line BL selected based on a column selection signal (not shown) to the data read/write circuit 400.

The data read/write circuit 400 inputs data to the bit lines BL via the column switch 300 when writing data, inputs thereto with a signal from a selected bit line BL via the column switch 300 when reading data, and the signal is output to the outside.

In addition, an activation signal ACT input to the internal voltage generating circuit 100 is a signal output from a command decode circuit (not shown) which detects a command signal input from the outside of the memory circuit 1000.

In addition, an output terminal of the internal voltage generating circuit 100 is connected to each power input terminal of each the word driver 200 as a load circuit, and supplies an operation voltage thereto.

Each word line WL is driven by the corresponding word driver 200. When a word line drive signal WD to drive the word lines WL is activated, the corresponding word lines WL are charged up to a voltage of the selection signal used to select the memory cell M500 by means of the word driver 200. The voltage of the selection signal is a voltage output by the internal voltage generating circuit 100.

Specifically, the internal voltage generating circuit (internal voltage generating circuit 100) includes the first voltage generating circuit (voltage generating circuit 110), and the second voltage generating circuit (voltage generating circuit 120) with higher current supply capability than that of the first voltage generating circuit (voltage generating circuit 110) and controls switching between activation and inactivation of the second voltage generating circuit (voltage generating circuit 120) using the internal signal CT of the first voltage generating circuit (voltage generating circuit 110), the internal voltage generating circuit (internal voltage generating circuit 100) outputs a control signal to select a particular memory element (memory cell M500) from the memory region (i.e., memory cell region 500) including the plurality of memory elements (i.e., memory cell M500), and a power voltage (operation voltage) is supplied to the output circuit (i.e., word driver 200) with varying power consumption.

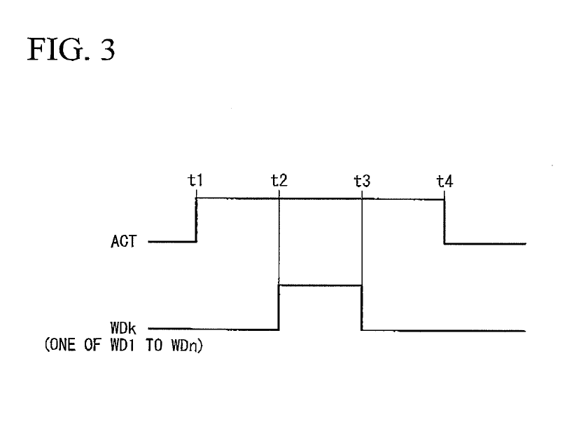

An operation of the memory circuit (semiconductor device) 1000 will be now described with reference to FIG. 3.

When an access (active) command (not shown) to read/write data into/from the memory circuit 1000 is input, the command decode circuit (not shown) decodes the command and turns the activation signal ACT to the internal voltage generating circuit 100 into an “H (high)” level as an active level at time t1. Thus, the internal voltage generating circuit 100 is activated to supply a desired operation voltage to each word driver 200.

At time t2, a word decoder (row decoder) (not shown) turns one signal WDk of the word line drive signals WD0 to WDn into an active level. The word line drive signal WDk turned into the active level is output to a word line WLk designated by a row address. Typically, although the row address is supplied along with the access command, since it requires a decoding process or the like, the word line drive signal WDk is slower than the activation signal ACT to the internal voltage generating circuit 100 and accordingly is turned into the active level.

The word driver 200, which received the word line drive signal WDk turned into the active level, drives the corresponding word lines WL up to that level with a voltage from the internal voltage generating circuit 100 as an operation voltage. At this time, since the plurality of memory cells M500 is connected to the word lines WL, its load capacitance, which is the total sum of gate capacitances of the FETs 502 of the memory cell M500, becomes very large. Accordingly, the driver 200 requires a considerable current (that is, a current large enough to charge the gate capacitances of the memory cell M500) in order to drive the word lines WL. Due to this, using only the voltage generating circuit 110 of the internal voltage generating circuit 100 cannot follow an operation of output voltage stabilization and thus the output voltage (that is, a word line driving voltage) starts to be lowered.

As a result, as described in connection with FIG. 1, the voltage generating circuit 120 with higher driving capability is activated to prevent the driving voltage from being lowered. Thus, the selected word line WLk is rapidly driven with a desired selection voltage (that is, a voltage exceeding a threshold voltage based on which it is determined that each memory cell M500 is selected). When the driving of the selected word line WLk has nearly ended, the voltage generating circuit 120 becomes inactivated.

A read or write command following the access command is supplied along with a column address, and as a result, the column switch 300 electrically connects a bit line BL1, which is selected based on a selection signal from the column decoder (not shown), to the data read/write circuit. Thus, a data reading or writing operation is performed for the memory cell M500-m1 arranged at an intersection of the selected word line WKk and bit line BL1.

At time t3 when the substantial data reading or writing operation for the selected memory cell M500-m1 has ended, the selected word line drive signal WDk is changed to a “L (low)” level which is an inactive level. Thereafter, when another word line drive signal is changed to an active level, the above-described operation is performed.

When an access to the memory circuit 1000 is completed, the command decoder returns the activation signal ACT to the “L (low)” level, which is the inactive level, at time t4. As a result, the internal voltage generating circuit 100 is also transitioned to an inactive state where a voltage output is stopped.

In this manner, the memory circuit 1000 can achieve desired voltage supply and stabilization at a high speed for the word driver 200 with large load capacitance and a selected word line WLk without wasteful power consumption.

In addition, the memory circuit 1000 including the phase-change elements 501 includes the FETs 502 to switch the current capacitance required to change a state of the phase-change elements 501 in each memory cell M500. The internal voltage generating circuit 100 can stabilize and supply a driving voltage of the word driver 200 to drive the word lines WL to which the plurality of the FETs 502 is connected.

The embodiments are not limited to the above-described embodiments but may be modified without departing from the spirit and scope of the present invention. Various components in the internal voltage generating circuit and the voltage generating circuits may be replaced with other elements having similar functions, and the number of configurations and form of connection thereof are not particularly limited.

In addition, in the circuit configuration shown in the above embodiments, polarities of power sources and circuit elements may be replaced with different polarities of power source and circuit elements with different conductivity.

In addition, the internal signal which is output from the voltage generating circuit with lower driving capability and is used for activation/inactivation of the voltage generating circuit with higher driving capability may be output at any appropriate position depending on the configuration of the voltage generating circuit with lower driving capability. For example, a multi-stage amplifier circuit may be added as a differential amplifier circuit in order to raise a gain. In this case, unlike the internal signal CT shown in FIG. 1, a signal whose level is increased with lowering of the output voltage VWL may be used to control activation/inactivation of the voltage generating circuit with higher driving capability. Of course, in this case, the threshold of the buffer 27 is set to be larger than the level of that signal in a normal operation.

In accordance with the foregoing embodiments, the circuit configuration described above is applied to the phase-change memory such as PRAM. It is possible that the circuit configuration described above is applied to any other available memories such as a resistance random access memory (RRAM). The resistance random access memory (RRAM) has memory cells, each of which has a variable resistance element. The variable resistance element includes a magneto-resistive element that shows variation of electric resistance upon application of a voltage pulse. Each of PRAM and RRAM has a function of varying resistance of a memory cell in response to information stored therein.

The above-described internal voltage circuit 100 may be integrated on any available semiconductor devices such as central processing units (CPU), micro control units (MCU), digital signal processors (DSP), application specific integrated circuits (ASIC), and application specific standard circuits (ASSP). The memory circuit 1000 can be integrated on any available semiconductor memories as described above. The memory circuit 1000 is applicable to semiconductor devices such as system-on-chip (SOC), multi-chip-package (MCP), and package-on-package (POP).

The transistors used in the foregoing embodiments should not be limited to MOS transistors (MOSFET) but may be other field effect transistors such as metal-insulator semiconductors (MISFET), and thin film transistors (TFT). It is also possible as a modification that the circuit may include one or more bipolar transistors. The pMOSFET is a mere example of the first conductivity type transistor. The nMOSFET is a mere example of the second conductivity type transistor.

It is apparent that the present invention is not limited to the above embodiments, but may be modified and changed without departing from the scope and spirit of the invention.

What is claimed is:

1. A semiconductor device comprising an internal voltage generating circuit which comprises:
a first voltage generating circuit;
a second voltage generating circuit having a higher current supply capability than the first voltage generating circuit; and
a control circuit that controls switching between activation and inactivation of the second voltage generating circuit, using a first internal signal of the first voltage generating circuit.

2. The semiconductor device according to claim 1, wherein the first voltage generating circuit, comprises a first output circuit that controls an output voltage of the first voltage generating circuit, the first output circuit receives a driving signal, the second voltage generating circuit also receives the driving signal as a second internal signal.

3. The semiconductor device according to claim 1, wherein the control circuit has a first threshold for switching between activation and inactivation of the second voltage generating circuit based on the first threshold, the first threshold is set so that a load current becomes exceeding a supply current at the first threshold, the load current is a current flowing through a load circuit that is connected commonly to outputs of the first and second voltage generating circuits, and the supply current is a current supplied from the first voltage generating circuit.

4. The semiconductor device according to claim 2, wherein the control circuit has a first threshold for switching between activation and inactivation of the second voltage generating circuit based on the first threshold, the first threshold is set so that a load current becomes exceeding a supply current at the first threshold, the load current is a current flowing through a load circuit that is connected commonly to outputs of the first and second voltage generating circuits, and the supply current is a current supplied from the first voltage generating circuit.

5. The semiconductor device according to claim 2, wherein the control circuit Comprises a buffer that receives the first internal signal, the buffer controls switching between activation and inactivation of the second voltage generating circuit,
the buffer has a second threshold at which the output from the buffer is inverted, the second threshold is set in relation to a first voltage value, of the first internal signal, and
the first voltage value is a voltage at which a load current becomes exceeding a supply current, the load current is a current flowing through a load circuit that is connected commonly to outputs of the first and second voltage generating circuits, and the supply current is a current supplied from the first output circuit of the first voltage generating circuit.

6. The semiconductor device according to claim 3, wherein the control circuit comprises a buffer that receives the first internal signal, the buffer controls switching between activation and inactivation of the second voltage generating circuit,
the buffer has a second threshold at which the output from the buffer is inverted, the second threshold is set in relation to a first voltage value of the first internal signal, and
the first voltage value is a voltage at which, a load current becomes exceeding a supply current, the load current is a current flowing through a load circuit that is connected commonly to outputs of the first and second voltage generating circuits, and the supply current is a current supplied from the first output circuit of the first voltage generating circuit.

7. The semiconductor device according to claim 2, wherein the first voltage generating circuit comprises a first differential amplifier circuit that compares a feedback voltage to a first reference voltage to generate the driving signal, the feedback voltage being generated based on the output voltage,
the second voltage generating circuit comprises:
a second differential amplifier circuit that compares the feedback voltage to a second reference voltage;
a second output circuit being driven by the second differential amplifier circuit, the second output circuit has an output that is commonly connected to the output of the first output circuit of the first voltage generating circuit; and
the control circuit supplies an output signal that is supplied to the second differential amplifier circuit, so as to switch between activation and inactivation of the second voltage generating circuit.

8. The semiconductor device according to claim 3, wherein the first voltage generating circuit comprises a first differential amplifier circuit that compares a feedback voltage to a first reference voltage to generate the driving signal, the feedback voltage being generated based on the output voltage,
the second voltage generating circuit comprises:
a second differential amplifier circuit that compares the feedback voltage to a second reference voltage;
a second output circuit being driven by the second differential amplifier circuit, the second output circuit has an output that is commonly connected to the output of the first output circuit of the first voltage generating circuit; and
the control circuit supplies an output signal that is supplied to the second differential amplifier circuit, so as to switch between activation and inactivation of the second voltage generating circuit.

9. The semiconductor device according to claim 6, wherein the first voltage generating circuit comprises a first differential amplifier circuit that compares a feedback voltage to a first reference voltage to generate the driving signal, the feedback voltage being generated based on the output voltage,
the second voltage generating circuit comprises:
a second differential amplifier circuit that compares the feedback voltage to a second reference voltage;
a second output circuit being driven by the second differential amplifier circuit, the second output circuit has an output that is commonly connected to the output of the first output circuit of the first voltage generating circuit; and
the control circuit supplies an output signal that is supplied to the second differential amplifier circuit, so as to switch between activation and inactivation of the second voltage generating circuit.

10. The semiconductor device according to claim 5, wherein the second differential amplifier circuit of the second voltage generating circuit is greater in amplification capability than the first differential amplifier circuit of the first voltage generating circuit.

11. A semiconductor device comprising an internal voltage generating circuit which comprises:
a first voltage generating circuit;
a second voltage generating circuit having a higher current supply capability than the first voltage generating circuit; and
a control circuit that controls switching between activation and inactivation of the second voltage generating circuit, using a first internal signal of the first voltage generating circuit,
wherein the internal voltage generating circuit is connected to a power of an output circuit, the output circuit varies current consumption when outputting a control signal that selects at least one memory elements in a plurality of memory elements,
the internal voltage generating circuit supplies the output circuit with a supply current that corresponds to the current consumption.

12. The semiconductor device according to claim 11, wherein the control circuit has a first threshold for switching between activation and inactivation of the second voltage generating circuit based on the first threshold, the first threshold is set so that a load current becomes exceeding a supply current at the first threshold, the load current is a current flowing through a load circuit that is connected commonly to outputs of the first and second voltage generating circuits, and the supply current is a current supplied from the first voltage generating circuit.

13. The semiconductor device according to claim 11, wherein the control circuit comprises a buffer that receives the first internal signal, the buffer controls switching between activation and inactivation of the second voltage generating circuit,
the buffer has a second threshold at which the output from the buffer is inverted, the second threshold is set in relation to a first voltage value of the first internal signal, and
the first voltage value is a voltage at which a current consumption becomes exceeding a supply current, the current consumption is a current flowing through the output circuit that is connected commonly to outputs of the first and second voltage generating circuits, and the supply current is a current supplied from the first voltage generating circuit.

14. The semiconductor device according to claim 12, wherein the control circuit comprises a buffer that receives the first internal signal, the buffer controls switching between activation and inactivation of the second voltage generating circuit,
the buffer has a second threshold at which the output from the buffer is inverted, the second threshold is set in relation to a first voltage value of the first internal signal, and
the first voltage value is a voltage at which a current consumption becomes exceeding a supply current, the current consumption is a current flowing through the output circuit that is connected commonly to outputs of the first and second voltage generating circuits, and the supply current is a current supplied from the first voltage generating circuit.

15. A semiconductor device comprising:
a plurality of word lines;
a plurality of bit lines;
a plurality of memory cells being arranged at crossing points of the word lines and the bit lines;
a plurality of word drivers that each drives the word line;
an internal voltage generating circuit that supplies an operation voltage to the word driver as a load circuit,
wherein the internal voltage generating circuit comprises:
a first voltage generating circuit;
a second voltage generating circuit having a higher current supply capability than the first voltage generating circuit; and
a control circuit that controls switching between activation and inactivation of the second voltage generating circuit, using a first internal signal of the first voltage generating circuit.

16. The semiconductor device according to claim 15, wherein the first voltage generating circuit is activated in response to issuance of an access command to the memory circuit,
a corresponding one of the word drivers supplies the operation voltage to a corresponding one of the word lines for driving the corresponding one of the word lines.

17. The semiconductor device according to claim 16, wherein the second voltage generating circuit is activated in response to a change of the internal signal, the change of the internal signal is caused by variation of the operational voltage, and the variation, of the operational voltage is caused by driving the corresponding word line.

18. The semiconductor device according to claim 15, wherein each of the memory cells comprises a memory element including a variable resistance.

19. The semiconductor device according to claim 15, wherein the control circuit has a first threshold for switching between, activation and inactivation of the second voltage generating circuit based on the first threshold, the first threshold is set so that a load current becomes exceeding a supply current at the first threshold, the load current is a current flowing through a load circuit that is connected commonly to outputs of the first and second voltage generating circuits, and the supply current is a current supplied from the first voltage generating circuit.

20. The semiconductor device according to claim 15, wherein the control circuit comprises a buffer that receives the first internal signal, the buffer controls switching between activation and inactivation of the second voltage generating circuit,
the buffer has a second threshold at which the output from the buffer is inverted, the second threshold is set in relation to a first voltage value of the first internal signal, the first voltage value is a voltage at which a current consumption becomes exceeding a supply current, the current consumption is a current flowing through the output circuit that is connected commonly to outputs of the first and second voltage generating circuits, and the supply current is a current supplied from the first voltage generating circuit.
